(19) United States
(12) Patent Application Publication
(10) Pub. No.: US 2013/0104955 A1
(43) Pub. Date: May 2, 2013

(54) PHOTOELECTRIC CONVERSION MODULE

(71) Applicants: Hyun-Chul KIM, Yongin-si (KR); Ji-Won Lee, Yongin-si (KR)

(72) Inventors: Hyun-Chul KIM, Yongin-si (KR); Ji-Won Lee, Yongin-si (KR)

(21) Appl. No.: 13/432,469

(22) Filed: Mar. 28, 2012

Related U.S. Application Data
(60) Provisional application No. 61/551,677, filed on Oct. 26, 2011.

(51) Int. Cl. H01L 31/05

(52) U.S. Cl. 136/244

(57) ABSTRACT

A photoelectric device includes a first substrate and a second substrate facing each other, a first cell between the first substrate and the second substrate, the first cell including respective electrodes on the first and second substrates, a second cell between the first substrate and the second substrate, the second cell being directly adjacent to the first cell and including respective electrodes on the first and second substrates, an electrode of the first cell being electrically connected to an electrode of the second cell by a connecting member, and at least one finger electrode in the first cell on at least one of the respective electrodes of the first cell.

### CROSS-REFERENCE TO RELATED APPLICATION

The present application claims priority under 35 U.S.C. §119(e) to U.S. Provisional Application No. 61/551,677, filed on Oct. 26, 2011, and entitled: “Photoelectric Conversion Module,” which is incorporated herein by reference in its entirety.

### BACKGROUND

1. Field

Embodiments relate to a photoelectric conversion module.

2. Description of the Related Art

Photoelectric conversion devices convert light energy into electric energy and have been studied as an energy source for replacing fossil fuels. As such, solar cells using sunlight have come into the spotlight.

Various types of solar cells having various driving principles have been investigated. Silicon or crystalline solar cells having a wafer shape and including a p-n semiconductor junction may be used, but the manufacturing costs thereof may be high due to the characteristics of processes for forming and handling semiconductor materials having a high degree of purity.

### SUMMARY

An embodiment is directed to a photoelectric device, including a first substrate and a second substrate facing each other, a first cell between the first substrate and the second substrate, the first cell including respective electrodes on the first and second substrates, a second cell between the first substrate and the second substrate, the second cell being directly adjacent to the first cell and including respective electrodes on the first and second substrates, an electrode of the first cell being electrically connected to an electrode of the second cell by a connecting member, and at least one finger electrode in the first cell on at least one of the respective electrodes of the first cell.

A first finger electrode in the first cell may contact a first end of the connecting member.

The first cell may include a plurality of finger electrodes spaced apart from the connecting member.

The respective electrodes of the first cell may include a first electrode on the first substrate and a second electrode on the second substrate, and the respective electrodes of the second cell may include a first electrode on the first substrate and a second electrode on the second substrate, and the first electrode of the first cell may include a first finger electrode at a surface of the first electrode, and the second electrode of the second cell may include a second finger electrode at a surface of the second electrode.

The connecting member may contact the first finger electrode of the first electrode of the first cell and contact the second finger electrode of the second electrode of the second cell.

The connecting member may be spaced apart from the first finger electrode of the first electrode of the first cell and may be spaced apart from the second finger electrode of the second electrode of the second cell.

The first finger electrode of the first electrode of the first cell may be aligned with the connecting member and may be aligned with the second finger electrode of the second electrode of the second cell.

The first finger electrode of the first electrode of the first cell may be aligned with the second finger electrode of the second electrode of the second cell, and the first finger electrode of the first electrode of the first cell and the second finger electrode of the second electrode of the second cell may be offset from the connecting member.

The first finger electrode of the first electrode of the first cell and the second finger electrode of the second electrode of the second cell may be located between two adjacent connecting members.

The first finger electrode of the first electrode of the first cell and the second finger electrode of the second electrode of the second cell may not be aligned with the connecting member.

The first finger electrode of the first electrode of the first cell may be offset from the second finger electrode of the second electrode of the second cell, and the connecting member may be between the first finger electrode of the first electrode of the first cell and the second finger electrode of the second electrode of the second cell.

The first finger electrode of the first electrode of the first cell may be between the connecting member and a second connecting member, and the second finger electrode of the second electrode of the second cell may be between the connecting member and a third connecting member.

The connecting member may be spaced apart from the first finger electrode of the first electrode of the first cell by a first predetermined distance, and may be spaced apart from the second finger electrode of the second electrode of the second cell by a second predetermined distance, the first and second predetermined distances each being about 25 mm or less.

The first and second predetermined distances may each be about 14 mm or more.

A plurality of first finger electrodes and a plurality of second finger electrodes may be arranged such that each of the finger electrodes extends away from the cell divider in a direction approximately perpendicular to the cell divider.

An electrode of the first cell may have a plurality of distinct finger electrodes disposed thereon.

Another embodiment is directed to a method of converting light to electricity, including directing the light into a photoelectric device, and converting the light to electricity using the photoelectric device, wherein the photoelectric device is a photoelectric device according to an embodiment.

### BRIEF DESCRIPTION OF THE DRAWINGS

Features will become apparent to those of skill in the art by describing in detail example embodiments with reference to the attached drawings in which:

FIG. 1 illustrates an upper plane view of a photoelectric conversion module according to an example embodiment, as viewed from above.

FIG. 2 illustrates an exploded perspective schematic view of a photoelectric conversion module according to an example embodiment.

FIG. 3 illustrates a cross-sectional view taken along a line of FIG. 1.

FIG. 4 illustrates a cross-sectional view taken along a line IV-IV of FIG. 1.

FIG. 5 illustrates a cross-sectional view taken along a line V-V of FIG. 1.

FIG. 6 illustrates a perspective view of a partial structure of a photoelectric conversion module, wherein neighboring photoelectric cells are electrically connected to each other via an island type connecting member, according to an example embodiment.

FIG. 7 illustrates a perspective view of a partial structure of a photoelectric conversion module, wherein neighboring photoelectric cells are electrically connected to each other via an island type connecting member, according to another example embodiment.

FIG. 8 illustrates a perspective view of a partial structure of a photoelectric module, wherein neighboring photoelectric cells are electrically connected to each other via an island type connecting member, according to another example embodiment.

FIG. 9 illustrates a perspective view of a partial structure of a photoelectric module, wherein neighboring photoelectric cells are electrically connected to each other via an island type connecting member, according to another example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. It will be understood that although the terms first and second are used herein to describe various elements, these elements should not be limited by these terms. These terms are only used to distinguish one element from another element.

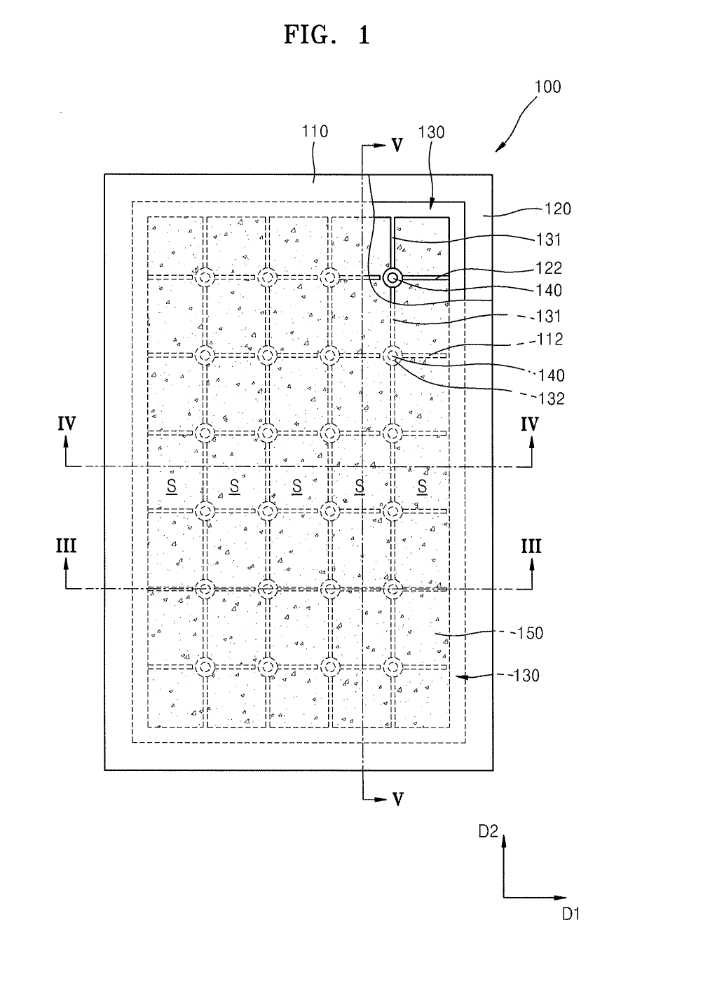

FIG. 1 illustrates an upper plane view of a photoelectric conversion module according to an example embodiment, as viewed from above.

Referring to FIG. 1, a photoelectric conversion module 100 includes a plurality of photoelectric cells S. The plurality of photoelectric cells S may be arranged in parallel to each other in one direction (e.g., with each photoelectric cell S extending in a direction D2 in FIG. 1, and being arranged adjacent to one another in a direction D1 in FIG. 1), and divided by a sealing member 130. The photoelectric cells S may be modularized by being physically supported by the sealing member 130 between a first substrate 110 and a second substrate 120, which face each other.

In the present example embodiment, an electrolyte 150 is filled inside the photoelectric cell S. The electrolyte 150 is sealed by the sealing member 130 that surround the entire photoelectric cells S while being arranged between the neighboring photoelectric cells S. For example, the sealing member 130 may be disposed around the electrolyte 150 to surround the electrolyte 150 so as to prevent the electrolyte 150 from leaking.

In the present example embodiment, the sealing member 130 includes at least one space defining the photoelectric cell S. The photoelectric cells S are spatially divided by a cell divider 131 disposed between the neighboring photoelectric cells S, and are electrically connected to each other by one or more island type connecting members 140 disposed along the cell divider 131. The cell divider 131 may be formed of an electrically insulating material. The island type connecting member 140 may be formed of an electrically conductive material.

In the present example embodiment, the sealing member 130 includes the cell divider 131 dividing the neighboring photoelectric cells S. One or more holes 132 may be formed along the cell divider 131 to accommodate the island type connecting member 140. The island type connecting member 140 may be disposed in the hole 132 formed on the sealing member 130. Thus, the island type connecting member 140 may be surrounded by a sealing material and the island type connecting member 140 may be protected from the electrolyte 150.

The island type connecting member 140 accommodated in the hole 132 may point-connect the neighboring photoelectric cells S. Thus, the plurality of photoelectric cells S may be connected in series via at least one connection point. A plurality of the island type connecting members 140 may electrically connect the neighboring photoelectric cells S. The island type connecting members may be spaced apart from each other along the cell divider 131.

As described above, the island type connecting member 140 may be protected from the electrolyte 150 by being surrounded by the sealing material. The cell divider 131 may have a thickness sufficient to spatially separate the neighboring photoelectric cells S, and thus a thickness of the cell divider 131 may be thin. Accordingly, generation of a dead area constituting a non-photoelectric conversion area formed between the photoelectric cells S forming the photoelectric conversion module 100 may be reduced.

In order to minimize dead area while improving efficiency of photoelectric conversion, first and second finger electrodes 112 and 122 may be disposed along, e.g., approximately perpendicular to, an arranged direction of the plurality of island type connecting member 140 (or a length direction of the photoelectric cell S).

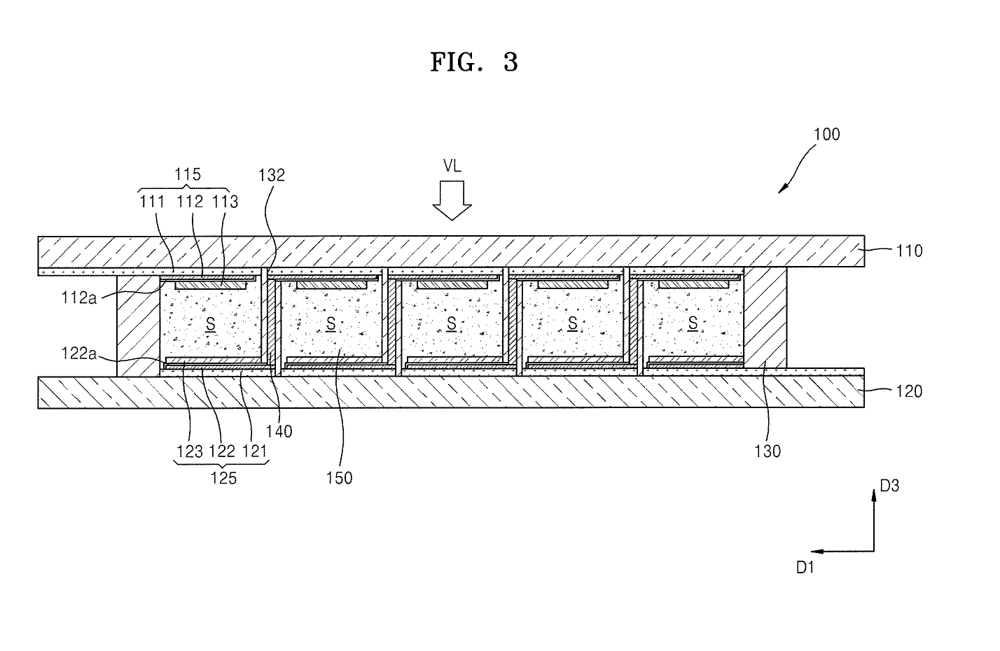

In an example embodiment, the island type connecting member 140 may contact and electrically connect a corresponding first finger electrode 112 to a corresponding second finger electrode 122 (see FIG. 3). The common electrical connection of the first finger electrode 112, the island type connecting member 140, and the second finger electrode 122 may form a ‘z’ shape (or backwards ‘z’ depending on the perspective) (see FIG. 3). The first and second finger electrodes 112 and 122 may be arranged parallel to each other to form a stripe pattern. In an implementation, the first and second finger electrodes 112 and 122 may electrically contact, and extend from, a corresponding island type connecting member 140 (see FIG. 3).

By using the first and second finger electrodes 112 and 122, a number of island type connecting members 140 may be significantly reduced. For example, when a length of a photoelectric cell is about 150 mm in a photoelectric conversion module that does not include a finger electrode, island type connecting members for point-connection may be arranged at intervals ranging from about 4 mm to about 9 mm. On the other hand, when a length of the photoelectric cell S of the photoelectric conversion module 100 that includes the first and second finger electrodes 112 and 122 is about 150 mm, the island type connecting members 140 for point-connection may be arranged at intervals ranging from about 9 mm to about 25 mm, and efficiency may also significantly increase.

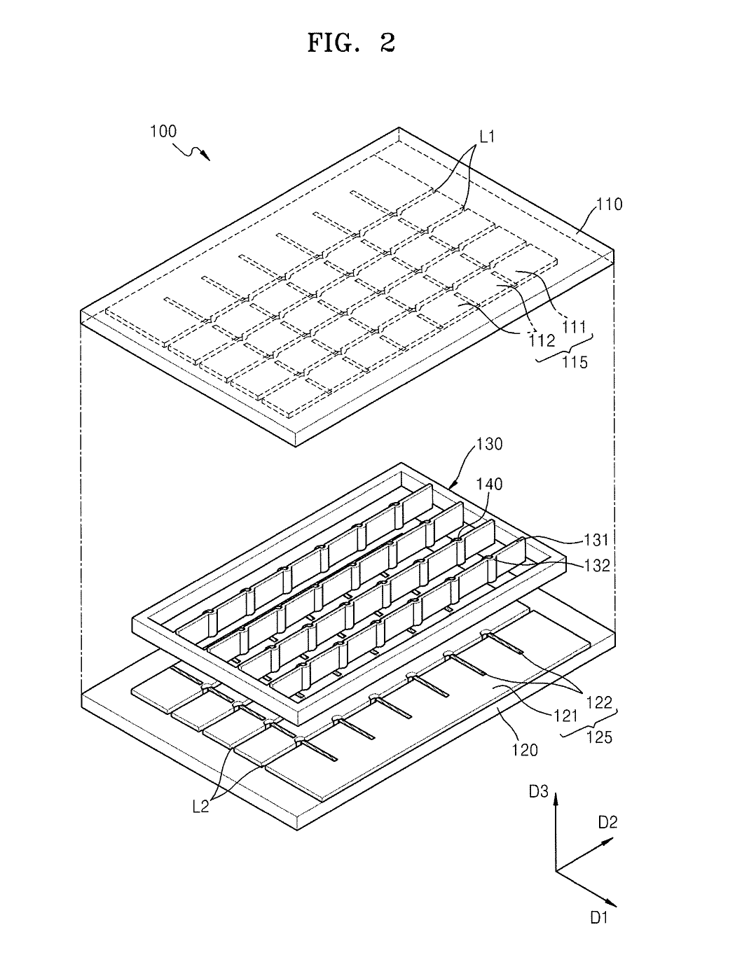

FIG. 2 illustrates an exploded perspective schematic view of a photoelectric conversion module according to an example embodiment. For convenience of description, FIG. 2 only shows a photoelectrode 111 and the first finger electrode 112 on the first substrate 110, and a counter electrode 121 and the second finger electrode 122 on the second substrate 120. The photoelectrode 111, the first finger electrode 112, and a semiconductor layer (not shown) may form a first electrode unit 115 of the photoelectric cell S. The counter electrode 121, the second finger electrode 122, and a catalyst layer (not shown) may form a second electrode unit 125 of the photoelectric cell S.

In the example embodiment shown in FIG. 2, the sealing member 130 is disposed between the first and second substrates 110 and 120 facing each other to prevent the electrolyte 150 from leaking, and defines the plurality of photoelectric cells S via the cell divider 131. The cell divider 131 includes the plurality of holes 132 to accommodate the island type connecting members 140, as described above with reference to FIG. 1, and the island type connecting members 140 disposed in the holes 132 may be spaced apart from each other along the cell divider 131.

A scribe line L1 (enabling an upper portion of the cell divider 131 to be combined to the first substrate 110) may be formed in the first electrode unit 115 on the first substrate 110. Also, a scribe line L2 (enabling a lower portion of the cell divider 131 to be combined to the second substrate 120) may be formed in the second electrode unit 135 on the second substrate 120. The upper and lower portions of the cell divider 131 may be combined to the first and second substrate 110 and 120 via the scribe lines L1 and L2, e.g., by using an adhesive material such as a hot melt adhesive, while directly contacting the first and second substrates 110 and 120.

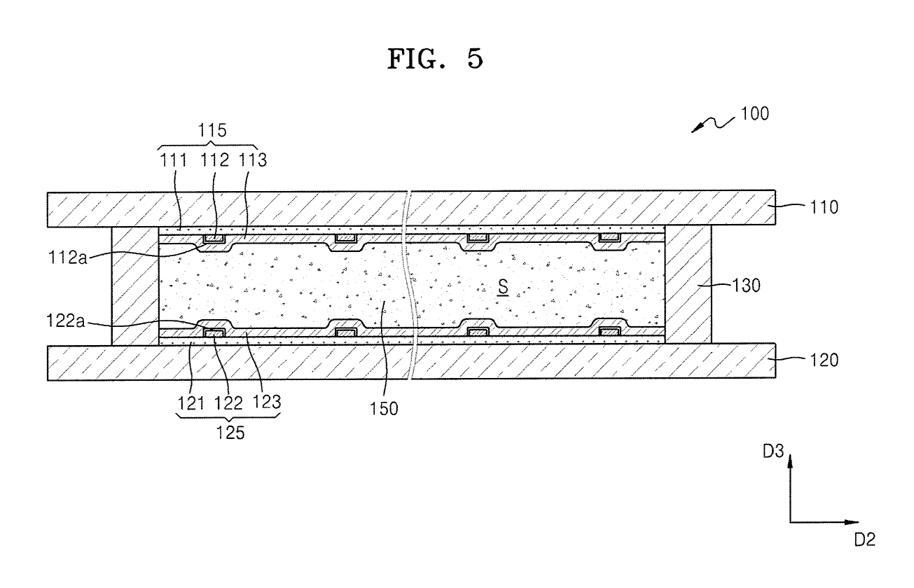

As can be seen in FIG. 2, a cell may extend across a number of finger electrodes 112, 122 (see also FIG. 5 showing a cross-section through a cell extending between opposing sides defined by sealing member 130). The first finger electrode 112 may be formed on the photoelectrode 111 and may extend in a direction approximately perpendicular to the cell divider 131. The first finger electrodes 112 may be parallel to each other to form a stripe pattern. The second finger electrodes 122 may be formed on the counter electrode 121 and may extend in a direction approximately perpendicular to the cell divider 131. The second finger electrodes 122 may be parallel to each other to form a stripe pattern.

A general finger electrode may be a comb type (hereinafter, referred to as a comb type finger electrode) including first finger units parallel to each other, and second finger units perpendicular to the first finger units and respectively connected to an end of each first finger unit. In contrast, a finger electrode according to an example embodiment may only include the first finger units parallel to each other from the comb type finger electrode. In the comb type finger electrode, the second finger unit of one photoelectric cell is covered by a sealing member so as to prevent the second finger unit from being exposed to a neighboring photoelectric cell. Accordingly, when the comb type finger electrode is used, a cell divider disposed between photoelectric cells may have a thickness that is greater than a thickness of the second finger unit so as to cover the second finger unit. In contrast, the first and second finger electrodes 112 and 122 according to the present example embodiment may only include the first finger units parallel to each other, and the need to increase a thickness of the cell divider 131 may be avoided. Accordingly, a dead area (constituting a non-photoelectric conversion area between the neighboring photoelectric cells S) may be reduced.

In the example embodiment shown in FIG. 2, six island type connecting members 140 are used to electrically connect the neighboring photoelectric cells S, but other numbers of the island type connecting members 140 may be used. Also, in FIG. 2, the first and second finger electrodes 112 and 122 correspond to the island type connecting member 140 in a one-to-one manner, but other arrangements may be used. For example, the first and second finger electrodes 112 and 122 may be further disposed (or may not be disposed) between the neighboring island type connecting members 140. Thus, the numbers of the first and second finger electrodes 112 and 122 may be more than (or less than) the number of island type connecting members 140 included in one cell divider 131 in FIG. 2.

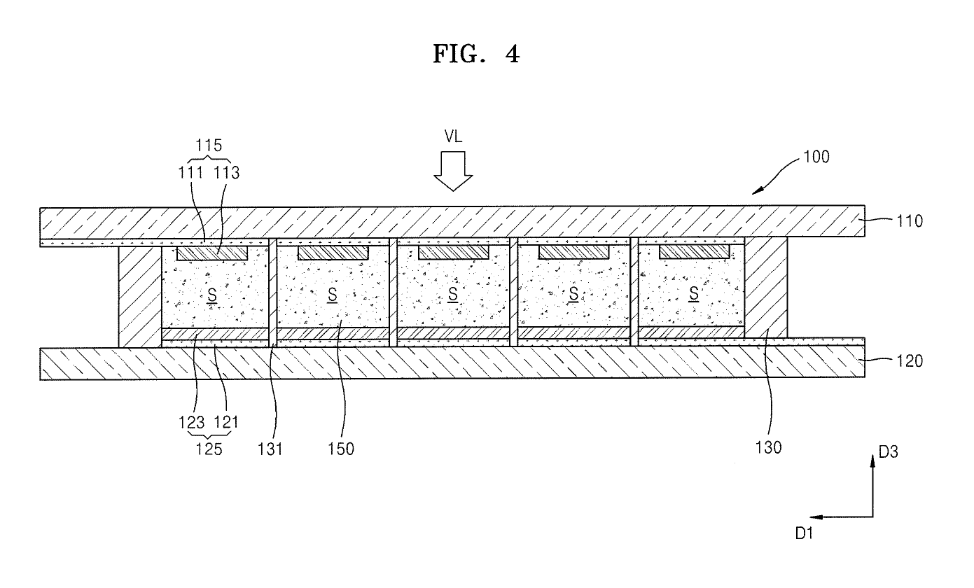

FIG. 3 illustrates a cross-sectional view taken along a line III-III of FIG. 1, FIG. 4 illustrates a cross-sectional view taken along a line IV-IV of FIG. 1, and FIG. 5 illustrates a cross-sectional view taken along a line V-V of FIG. 1.

The photoelectric cells S may be point-connected via the island type connecting members 140 in the photoelectric conversion module 100 according to an example embodiment. Thus, a region with the island type connecting member 140 of FIG. 3 and a region without the island type connecting member 140 of FIG. 4 co-exist. Also, the photoelectric conversion module 100 according to an example embodiment may include the first and second finger electrodes 112 and 122 approximately perpendicular to an arranged direction of the photoelectric cells S. Thus, the photoelectric cells S may include the first and second finger electrodes 112 and 122 as shown in FIG. 5.

Referring to FIGS. 3 through 5, the photoelectric conversion module 100 may include the first and second substrates 110 and 120 facing each other, and the plurality of photoelectric cells S (defined by the sealing member 130) may be formed between the first and second substrates 110 and 120. The island type connecting member 140 may be disposed between the neighboring photoelectric cells S to connect the neighboring photoelectric cells S. The first and second electrode units 115 and 125 (for performing photoelectric conversion) may be formed on the first and second substrates 110 and 120, and the electrolyte 150 may be disposed between the first and second electrode units 115 and 125.

The first and second substrates 110 and 120 may have an approximately rectangular shape. The first substrate 110 may be a light-receiving substrate and may be formed of a transparent material having high light transmittance. The first substrate 110 may be a glass substrate. In another implementation, the first substrate 110 may be formed of bendable plastic, such as polyethyleneterephthalate (PET), polycarbonate (PC), polyimide (PI), polyethylenenaphthalate (PEN), or polyethersulfone (PES).

The second substrate 120 may be a counter substrate and may be disposed to face the first substrate 110 constituting a light-receiving substrate. Although a counter substrate is not specifically required to be transparent, it may be formed of a transparent material to receive light VL from both sides so as to increase efficiency of photoelectric conversion. Thus, the second substrate 120 may be formed of the same material as the first substrate 110. For example, if the photoelectric conversion module 100 is used for building integrated photovoltaic (BIPV) installed in a structure such as a window frame, the first and second substrates 110 and 120 may both be formed of a transparent material so as not to block the light VL transmitted to the indoors.

The first and second substrates 110 and 120 may be adhered to each other while having a space therebetween for the sealing member 130 to be disposed. The first and second electrode units 115 and 125 may be respectively disposed on the first and second substrates 110 and 120. The first electrode unit 115 may include the photoelectrode 111, the first finger electrode 112, and a semiconductor layer 113 adsorbing photosensitive dye molecules, and the second electrode unit 125 may include the counter electrode 121, the second finger electrode 122, and a catalyst layer 123.

The photoelectrode 111 may operate as a negative electrode of the photoelectric conversion module 100 and provide a current path by collecting electrons generated according to conversion transformation. In the present example embodiment, the light VL incident through the photoelectrode 111 operates as an excitation source of dye molecules adsorbed to the semiconductor layer 113. The photoelectrode 111 may be formed of a transparent conducting oxide (TCO) having electric conductivity and transparency, such as indium tin oxide (ITO), fluorine doped tin oxide (FTO), or antimony doped tin oxide (ATO).

The photoelectrode 111 may be formed to increase efficiency of forming electrons. The photoelectrode 111 may have high transparency so that sunlight easily reaches the dye molecules. The first finger electrode 112 may be disposed on the photoelectrode 111 to offset relatively high electric resistance of the photoelectrode 111, and thus efficiency may be increased.

As described above, the first finger electrode 112 may be formed on the photoelectrode 111, and may reduce electric resistance of the photoelectrode 111. The first finger electrode 112 may be formed of a metal having excellent electric conductivity, such as silver (Ag) or aluminum (Al). Multiple first finger electrodes 112 may be disposed in parallel to each other to form a stripe pattern. The electric resistance of the first finger electrode 112 may be lower than that of the photoelectrode 111. Thus, current flow may be enhanced. In an implementation, the first finger electrode 112 may be covered with a protection layer 112a to protect the first finger electrode 112 from the electrolyte 150.

The semiconductor layer 113 may be formed of a nano-sized semiconductor oxide layer. The oxide layer may include one or more metals such as cadmium (Cd), zinc (Zn), indium (In), lead (Pb), molybdenum (Mo), tungsten (W), antimony (Sb), titanium (Ti), silver (Ag), manganese (Mn), tin (Sn), zirconium (Zr), strontium (Sr), gallium (Ga), silicon (Si), and chromium (Cr). The nano-sized semiconductor oxide layer may have a structure in which a plurality of nanometer sized wide band gap semiconductor particles are stacked on each other.

A photosensitive dye, for example, dye molecules formed of a ruthenium (Ru) complex compound, may be chemically adsorbed onto surfaces of the nanometer sized wide band gap semiconductor particles. The dye molecules may be molecules showing adsorption in a visible ray band and quickly transferring electrons from a light excitation state to the semiconductor layer 113. For example, the dye molecules may include the Ru complex compound. Also, the dye molecules may be thiophene, phthalocyanine, porphyrin, indoline, or an organic substance containing quinoline, and derivatives thereof.

The dye molecules adsorbed to the semiconductor layer 113 may absorb the light VL incident through the first substrate 110, and electrons of the dye molecules may be excited from a ground state to an excited state. The excited electrons may be transferred to a conduction band of the semiconductor layer 113 via electric bond between the dye molecules and the semiconductor layer 113, reach the photoelectrode 111 through the semiconductor layer 113 after transference, and form a driving current for driving an external circuit (not shown) by being extracted outside via the photoelectrode 111.

The counter electrode 121 may operate as a positive electrode of the photoelectric conversion module 100. The counter electrode 121 may participate in reduction of the electrolyte 150. For example, the electrons of the dye molecules adsorbed to the semiconductor layer 113 may be excited by absorbing the light VL, and the excited electrons may be extracted to the outside through the photoelectrode 111. The photosensitive dye that lost electrons may be reduced again by collecting electrons provided via oxidation of the electrolyte 150. The oxidized electrolyte 150 may be reduced by the electrons that reach the counter electrode 121 through the external circuit, and thus an operation cycle of photoelectric conversion may be completed.

Like the photoelectrode 111, the counter electrode 121 may be formed of a TCO having electric conductivity and transparency, such as ITO, FTO, or ATO.

The second finger electrode 122 may be formed on the counter electrode 121 so as to compensate relatively high electric resistance of the counter electrode 121. The second finger electrode 122 may include a metal having excellent electric conductivity, such as Ag or Al, and multiple second finger electrodes 122 may be parallel to each other to form a stripe pattern. The electric resistance of the second finger electrode 122 may be lower than that of the counter electrode 121. Thus, current flow may be enhanced. The second finger electrode 122 may be covered by a protection layer 122a to be protected from the electrolyte 150.

The catalyst layer 123 may be formed on the counter electrode 121 and the protection layer 122a. The catalyst layer 123 may include a platinum (Pt) or carbon (C) thin film. The catalyst layer 123 may operate as a reduction catalyst for receiving electrons from the external circuit. Also, by depositing a Pt thin film on the catalyst layer 123, the light VL incident through the photoelectrode 111 may be reflected, thereby increasing conversion efficiency of sunlight.

The electrolyte 150 may be disposed between the first and second electrode units 115 and 125, for example, between the semiconductor layer 113 and the catalyst layer 123. The electrolyte 150 may include an iodine-based oxidation-reduction liquid electrolyte (I₃⁻/I⁻). The electrolyte 150 may reduce the oxidized dye molecules. In the present example embodiment, a liquid electrolyte is used as the electrolyte 150, but the electrolyte 150 may be a solid type or gel type.

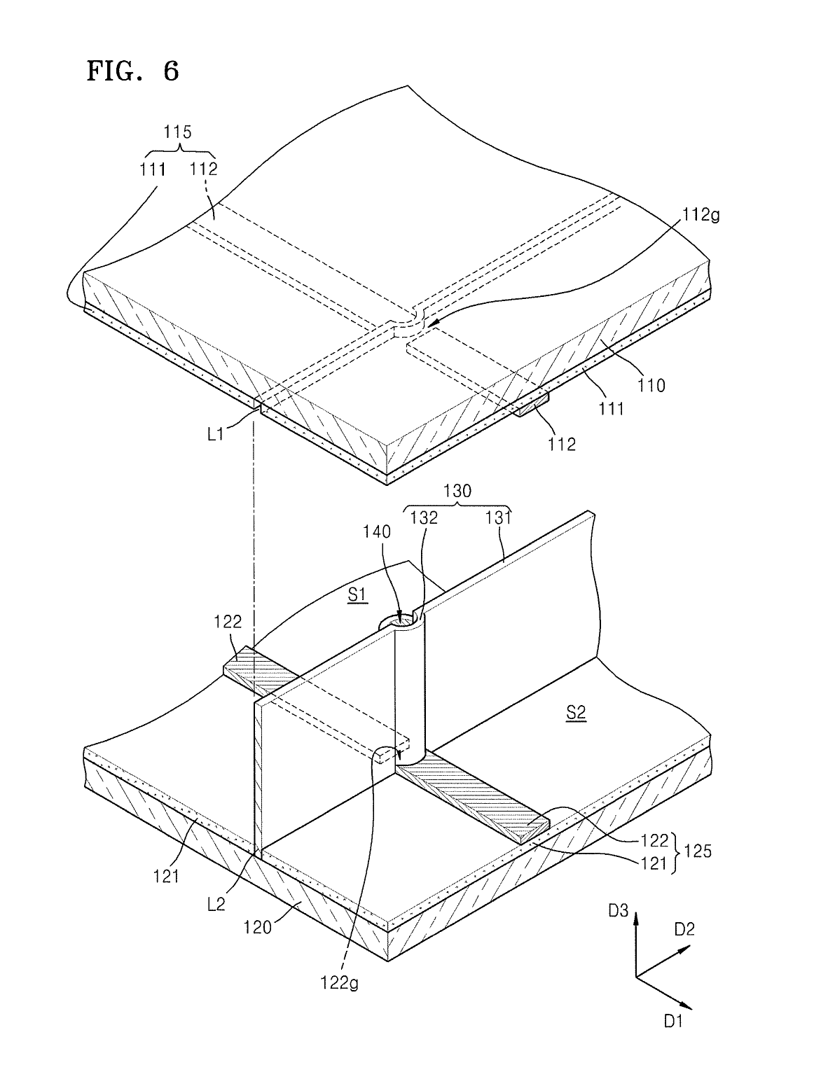

FIG. 6 illustrates a perspective view of a partial structure of a photoelectric conversion module, wherein neighboring photoelectric cells are electrically connected to each other via an island type connecting member, according to an example embodiment.

For convenience of description, FIG. 6 only illustrates the photoelectrode 111 and the first finger electrode 112 of the first electrode unit 115, and the counter electrode 121 and the second finger electrode 122 of the second electrode unit 125, and does not illustrate the semiconductor layer, the catalyst layer, and the protection layers of the first and second finger electrodes 112 and 122.

In the example embodiment shown in FIG. 6, photoelectric cells S1 and S2 are disposed across the cell divider 131 of the sealing member 130, and the sealing member 130 is disposed between the first and second substrates 110 and 120 facing each other. The photoelectrode 111 is formed on the first substrate 110, the counter electrode 121 is formed on the second substrate 120, and the scribe lines L1 and L2 are formed in the photoelectrode 111 and the counter electrode 121 so that the cell divider 131 and the first and second substrates 110 and 120 are combined to each other. The first and second substrates 110 and 120 may be spaced apart from each other and supported by the cell divider 131.

In the present example embodiment, the neighboring photoelectric cells S1 and S2 are connected in series by the island type connecting member 140 included in the hole 132 of the sealing member 130. For example, the island type connecting member 140 may contact the first electrode unit 115 of the photoelectric cell S1 (disposed at left in FIG. 6) and, at the same time, may contact the second electrode unit 125 of the photoelectric cell S2 (disposed at right in FIG. 6), thereby connecting the photoelectric cells S1 and S2 in series. An upper portion of the island type connecting member 140 may contact the first finger electrode 112 of the photoelectric cell S1 (at left) and a lower portion of the island type connecting member 140 may contact the second finger electrode 122 of the photoelectric cell S2 (at right). Further, there may be a gap 122g between the island type connecting member 140 and the second finger electrode 122 of the photoelectric cell S1 (at left), such that the island type connecting member 140 is spaced apart from the second finger electrode 122 of the photoelectric cell S1, and a gap 112g between the island type connecting member 140 and the first finger electrode 112 of the photoelectric cell S2 (at right), such that the island type connecting member 140 is spaced apart from the first finger electrode 112 of the photoelectric cell S2.

The first and second finger electrodes 112 and 122 may extend in a direction approximately perpendicular to the cell divider 131. The first and second finger electrodes 112 and 122 may be electrically connected to the island type connecting member 140 via physical contact. The first and second finger electrodes 112 and 122 according to the present example embodiment may extend in the direction approximately perpendicular to the cell divider 131 and may be parallel to each other. Relative to the comb type finger electrode described above, the first and second finger electrodes 112, 122 may not be coupled by a perpendicular connecting portion, and thus the cell divider 131 according to the present example embodiment may formed with a minimal thickness sufficient to spatially divide the neighboring photoelectric cells S1 and S2. Accordingly, a thickness of the cell divider 131 may be reduced and, thereby, a dead area may be reduced.

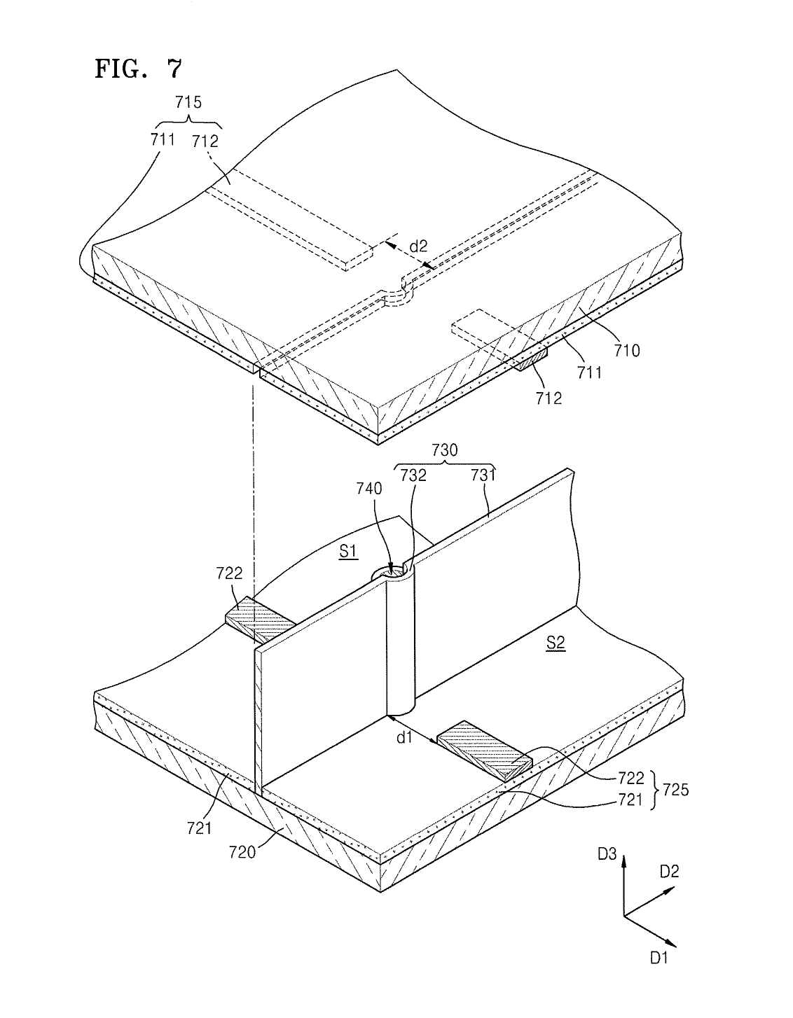

FIG. 7 illustrates a perspective view of a partial structure of a photoelectric conversion module, wherein neighboring photoelectric cells are electrically connected to each other via an island type connecting member, according to another example embodiment.

For convenience of description, FIG. 7 illustrates only a photoelectrode 711 and a first finger electrode 712 of a first electrode unit 715, and only a counter electrode 721 and a second finger electrode 722 of a second electrode unit 725. A semiconductor layer, a catalyst layer, and protection layers of the first and second finger electrodes 712 and 722 are not shown.

In the example embodiment shown in FIG. 7, the photoelectric cells S1 and S2 are disposed across a cell divider 731 of a sealing member 730, which is disposed between first and second substrates 710 and 720 facing each other. The photoelectrode 711 is formed on the first substrate 710, the counter electrode 721 is formed on the second substrate 720, and the first and second substrates 710 and 720 may be spaced apart from each other while being supported by the cell divider 731. The first and second finger electrodes 712 and 722 may extend in a direction approximately perpendicular to the cell divider 731, and may be spaced apart from each other to form a stripe pattern.

In the photoelectric conversion module according to the present example embodiment, an island type connecting member 740 is disposed in a hole 732, and is electrically connected to the first electrode unit 715 of the photoelectric cell S1 at left, and, at the same time, is electrically connected to the second electrode unit 725 of the photoelectric cell S2 at right, thereby connecting the photoelectric cells S1 and S2 in series. An upper portion of the island type connecting member 740 may be electrically connected to the photoelectrode 711 via direct contact, and a lower portion of the island type connecting member 740 may be electrically connected to the counter electrode 721 via direct contact, thereby electrically connecting the neighboring photoelectric cells S1 and S2. However, in the present example embodiment, the first and second finger electrodes 712 and 722 do not directly contact the island type connecting member 740. Rather, the first and second finger electrodes 712 and 722 may be respectively spaced apart from the cell divider 731 (which accommodates the island type connecting member 740) by predetermined distances d2 and d1.

The predetermined distances d1 and d2 may be, e.g., about 14 mm to about 25 mm. When the predetermined distances d1 and d2 are, e.g., more than 25 mm, current density may deteriorate, and thus photoelectric conversion efficiency may deteriorate.

By disposing the first and second finger electrodes 712 and 722 apart from the cell divider 731 by the predetermined distances d1 and d2, manufacturing costs of the photoelectric conversion module may be reduced without significantly affecting functions of the first and second finger electrodes 712 and 722. Also, by forming the first and second finger electrodes 712 and 722 to be short, an area of the first and second finger electrodes 712 and 722 that blocks light may be reduced, thereby increasing photoelectric conversion efficiency.

The first and second finger electrodes 712 and 722 according to the present example embodiment may extend in a direction approximately perpendicular to the cell divider 731 and may be parallel to each other. Accordingly, the thickness of the cell divider 731 according to the present example embodiment may be minimized to a thickness sufficient to spatially divide the neighboring photoelectric cells S1 and S2. Accordingly, a thickness of the cell divider 731 may be thin, and thus a dead area may be reduced.

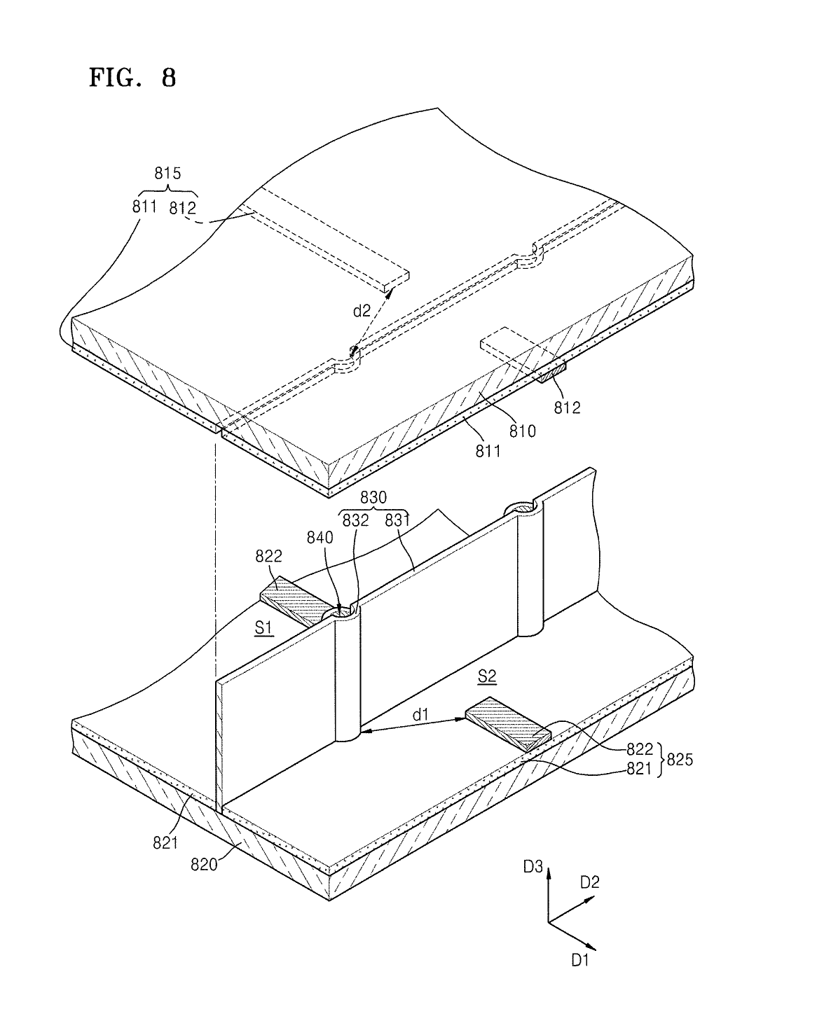

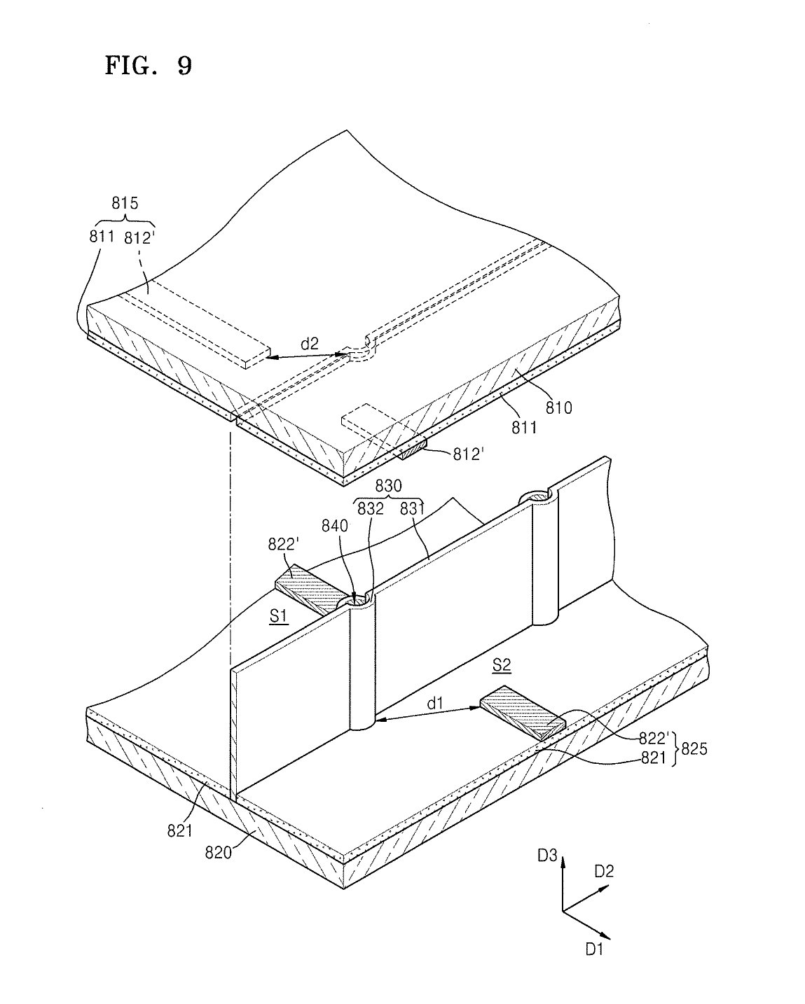

FIGS. 8 and 9 illustrate further example embodiments having the same general structure as that shown in FIG. 7. However, in FIGS. 8 and 9, first and second finger electrodes 812, 812′, 822, 822′ are offset from, i.e., not aligned with, island type connecting members 840.

In more detail, in the example embodiment shown in FIG. 8, the first and second finger electrodes 812, 822 are substantially perpendicular to the cell divider 831 and lie between two island type connecting members 840. The first finger electrodes 812 on the first substrate 810 are aligned with the second finger electrodes 822 on the second substrate 820 in the vertical direction D3, i.e., one above the other.

In the example embodiment shown in FIG. 9, the first and second finger electrodes 812′, 822′ are not aligned with each other in the vertical direction D3. The first and second finger electrodes 812′, 822′ on the first and second substrates 810,820 can therefore be seen to alternate in position along the first and second substrates 810, 820.

By way of summation and review, dye-sensitized solar cells may include a photosensitive dye (for generating excited electrons in response to visible light), a semiconductor material (for receiving the excited electrons), and an electrolyte (for reacting with the excited electrons in an external circuit). Dye-sensitized solar cells may have high photoelectric conversion efficiency compared to the silicon solar cells, and thus may be of interest for the next generation of solar cells. Multiple dye-sensitized solar cells may be electrically connected to one another in series. A series connection structure of such dye-sensitized solar cells may include a Z type, a W type, a monolith type, or an in-plane type. A conducting structure (for connecting adjacent cells) may be used in the Z type. Such a structure could reduce the light receiving area and increase electrical resistance.

As described above, photoelectric conversion modules according to example embodiments may use the island type connecting member. Thus, a dead area between the neighboring photoelectric cells may be reduced. Further, the thickness of the cell divider may be thin (except for the hole for accommodating the island type connecting member), such that the area of the dead area may be reduced.

Also, by forming the plurality of finger electrodes parallel to each other and approximately perpendicular to the cell divider, instead of a comb type finger electrode, the thickness of the cell divider is not unnecessarily increased, and thus the area of the dead area may be minimized. Moreover, by using the first and second finger electrodes, the number of island type connecting member may be reduced.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope as set forth in the following claims.

What is claimed is:

1. A photoelectric device, comprising:
a first substrate and a second substrate facing each other;
a first cell between the first substrate and the second substrate, the first cell including respective electrodes on the first and second substrates;
a second cell between the first substrate and the second substrate, the second cell being directly adjacent to the first cell and including respective electrodes on the first and second substrates, an electrode of the first cell being electrically connected to an electrode of the second cell by a connecting member; and
at least one finger electrode in the first cell on at least one of the respective electrodes of the first cell.

2. The photoelectric device as claimed in claim 1, wherein a first finger electrode in the first cell contacts a first end of the connecting member.

3. The photoelectric device as claimed in claim 1, wherein the first cell includes a plurality of finger electrodes spaced apart from the connecting member.

4. The photoelectric device as claimed in claim 1, wherein:
the respective electrodes of the first cell include a first electrode on the first substrate and a second electrode on the second substrate, and the respective electrodes of the second cell include a first electrode on the first substrate and a second electrode on the second substrate, and
the first electrode of the first cell includes a first finger electrode at a surface of the first electrode, and the second electrode of the second cell includes a second finger electrode at a surface of the second electrode.

5. The photoelectric device as claimed in claim 4, wherein the connecting member contacts the first finger electrode of the first electrode of the first cell and contacts the second finger electrode of the second electrode of the second cell.

6. The photoelectric device as claimed in claim 4, wherein the connecting member is spaced apart from the first finger electrode of the first electrode of the first cell and is spaced apart from the second finger electrode of the second electrode of the second cell.

7. The photoelectric device as claimed in claim 6, wherein the first finger electrode of the first electrode of the first cell is aligned with the connecting member and is aligned with the second finger electrode of the second electrode of the second cell.

8. The photoelectric device as claimed in claim 6, wherein the first finger electrode of the first electrode of the first cell is aligned with the second finger electrode of the second electrode of the second cell, and the first finger electrode of the first electrode of the first cell and the second finger electrode of the second electrode of the second cell are offset from the connecting member.

9. The photoelectric device as claimed in claim 8, wherein the first finger electrode of the first electrode of the first cell and the second finger electrode of the second electrode of the second cell are located between two adjacent connecting members.

10. The photoelectric device as claimed in claim 8, wherein the first finger electrode of the first electrode of the first cell and the second finger electrode of the second electrode of the second cell are not aligned with the connecting member.

11. The photoelectric device as claimed in claim 6, wherein the first finger electrode of the first electrode of the first cell is offset from the second finger electrode of the second electrode of the second cell, and the connecting member is between the first finger electrode of the first electrode of the first cell and the second finger electrode of the second electrode of the second cell.

12. The photoelectric device as claimed in claim 11, wherein the first finger electrode of the first electrode of the first cell is between the connecting member and a second connecting member, and the second finger electrode of the second electrode of the second cell is between the connecting member and a third connecting member.

13. The photoelectric device as claimed in claim 6, wherein the connecting member is spaced apart from the first finger electrode of the first electrode of the first cell by a first predetermined distance, and is spaced apart from the second finger electrode of the second electrode of the second cell by a second predetermined distance, the first and second predetermined distances each being about 25 mm or less.

14. The photoelectric device as claimed in claim 13, wherein the first and second predetermined distances are each about 14 mm or more.

15. The photoelectric device as claimed in claim 4, wherein a plurality of first finger electrodes and a plurality of second finger electrodes are arranged such that each of the finger electrodes extends away from the cell divider in a direction approximately perpendicular to the cell divider.

16. The photoelectric device as claimed in claim 1, wherein an electrode of the first cell has a plurality of distinct finger electrodes disposed thereon.

17. A method of converting light to electricity, comprising:
directing the light into a photoelectric device; and
converting the light to electricity using the photoelectric device, wherein:
the photoelectric device is the photoelectric device as claimed in claim 1.
